(19) United States
(12) Patent Application Publication
(10) Pub. No.: US 2010/0026630 A1
(43) Pub. Date: Feb. 4, 2010

(54) Electronic device

(75) Inventor: Tsuyoshi Kuribayashi, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/588,168

(22) Filed: Oct. 6, 2009

Related U.S. Application Data
(63) Continuation of application No. PCT/JP2007/058187, filed on Apr. 13, 2007.

(51) Int. Cl. G06F 3/02; H01H 9/00; H05K 5/00

(52) U.S. Cl. 345/168; 200/314; 174/520

(57) ABSTRACT

The present invention relates to an electronic device such as a notebook-size personal computer and a portable terminal, and provides an electronic device having high visibility and of low cost. An electronic device includes a calculation unit and plural light sources. The calculation unit incorporates a keyboard disposed on a top surface of the electronic device and an electronic circuit (not illustrated) to perform calculation processing according to an operation of the keyboard. The plural light sources are arranged in a deep side and on both sides of the calculation unit, to illuminate the keyboard in an obliquely inward direction. An LED having directivity may be used as the light sources.

### CROSS-REFERENCE TO RELATED APPLICATION

This is a continuation application of PCT/JP2007/058187, filed on Apr. 13, 2007.

### TECHNICAL FIELD

The present invention relates to an electronic device such as a notebook-size personal computer and a portable terminal.

### BACKGROUND ART

An electronic device such as a notebook-size personal computer (hereafter, a notebook PC) or a portable terminal is often used under a room light. Using such an electronic device in a dark place involves a problem that it is uncomfortable to operate the electronic device due to difficulty in recognizing the keyboard.

Therefore, to enhance the visibility of a keyboard in a dark place, there has been disclosed a keyboard equipped with a light source to illuminate a keyboard section of a personal computer (See Japanese Laid-open Patent Publication No. H08-314598, for example). There has been also disclosed a lighting unit designed to enhance the visibility of a keyboard by arranging a light source to emit black light as well as a material to emit a visible light by an irradiation of the black light emitted from the light source, placed on each key of the keyboard or in a close proximity of the keyboard (See Japanese Laid-open Patent Publication No. 2005-196312, for example).

The keyboard disclosed in the Japanese Laid-open Patent Publication No. H08-314598 has a light source on a deep side of the keyboard. Since an operator may be probably dazzled by light emitted from the light source, the keyboard has a protection cover to block the direct entrance of the light from the light source into the eyes of the operator. However, there remains a problem that light reflected from the keyboard enters the eyes of the operator.

On the other hand, the keyboard lighting unit disclosed in the Japanese Laid-open Patent Publication No. 2005-196312 has a problem of cost increase, since the lighting unit uses black light, a material responsive to the black light is required at the time of printing a character on the keyboard.

### DISCLOSURE OF INVENTION

The present invention is made in consideration of the above-described circumstances, and an object in one aspect of the invention is to provide an electronic device having high visibility and of low cost.

According to an aspect of the invention, a first electronic device of the present invention includes a calculation unit incorporating a keyboard disposed on a top surface of the electronic device and an electronic circuit to perform calculation processing according to an operation of the keyboard; and plural light sources arranged in a deep side and on both sides of the calculation unit, to illuminate the keyboard in an obliquely inward direction.

According to the first electronic device of the present invention, provision of the plural light sources to illuminate the keyboard in an obliquely inward direction may prevent light reflected from the keyboard from entering into the eyes of an operator, and therefore an electronic device having high visibility and of low cost may be obtained.

The calculation unit may have wall sections formed to be higher in one step with standing walls, in the deep side and at least on both sides of the calculation unit, and the light sources may be arranged in the wall sections.

The above-described structure of the first electronic device enables the plural light sources to be arranged in the wall section that is an appropriate portion in the calculation unit.

Portions on both sides of the calculation unit of the standing walls may be formed in an obliquely inward direction, and the light sources may be arranged in portions formed in the obliquely inward direction of the standing walls.

With the above-described structure of the first electronic device, the keyboard is illuminated in an obliquely inward direction by the plural light sources arranged in the wall section that is the appropriate portion in the calculation unit, and therefore an electronic device having high visibility and of low cost may be obtained.

The electronic device may include a display unit having a display screen hinged openably and closably to the calculation unit in the deep side of the calculation unit, and the wall sections may be formed to have a height where the wall sections form a same plane as the display unit closed on the calculation unit.

With the above-described structure of the first electronic device, the shape of the electronic device becomes compact when the display unit is closed, and therefore it is possible to improve portability and safekeeping property of the electronic device.

The display unit may be connected to the calculation unit openably and closably as well as rotatably in two axes.

The above-described structure of the first electronic device improves the visibility of the display section when the display unit is opened to operate the keyboard.

According to another aspect of the invention, a second electronic device of the present invention includes a calculation unit incorporating a keyboard disposed on a top surface of the electronic device and an electronic circuit to perform calculation processing according to an operation of the keyboard; a display unit having a display screen hinged openably and closably to the calculation unit in a deep side of the calculation unit; and plural light sources arranged in the deep side and on both sides of the calculation unit, to illuminate the keyboard in an obliquely inward direction.

With the above-described structure of the second electronic device, provision of the plural light sources to illuminate the keyboard in an obliquely inward direction may prevent light reflected from the keyboard from entering into the eyes of an operator, and therefore an electronic device having high visibility and of low cost may be obtained.

The display unit may be connected to the calculation unit openably and closably as well as rotatably in two axes.

The above-described structure of the second electronic device improves the operability when the display unit is opened to operate the electronic device.

According to the present invention, it is possible to realize an electronic device having high visibility and of low cost.

According to yet another aspect of the invention, a third electronic device of the present invention includes a first housing equipped with an operation section on a top surface thereof; and a second housing being hinged to the first housing openably and closably and having a predetermined thickness, wherein the first housing includes a wall section including a standing wall having an approximately same height as the predetermined thickness in a portion that does not face the second housing when the second housing is cause to be in a closed state; and a light source arranged on the wall section to illuminate the operation section.

According to the third electronic device of the present invention, an electronic device having high visibility may be obtained without causing obstruction in a closing operation of the second housing on the first housing. Furthermore, the shape of the electronic device becomes compact when the second housing is closed, thereby improving portability and safekeeping property of the electronic device.

An external shape of the first housing may be approximately quadrilateral, the second housing may be hinged to the first housing at a position lying close to a side of the external shape of the first housing, and the wall section may be formed on a side of the side to which the first housing is hinged.

Furthermore, the second housing may be hinged to the first housing at a central position of the side, and the wall section may be formed lying close to both ends from the central position of the side. Additionally, the second housing may be hinged to the first housing openably and closably as well as rotatably in two axes. With these structures, the wall section prevents the second housing from rattling when the second housing is closed on the first housing. Especially, if the second housing is connected to the first housing by a two-axis hinge, a significant effect may be obtained, as it is possible to restrict a lateral movement of the second housing to the first housing in the closed state as well. In this way, with the wall section, the movement of the second housing is restricted (rattling is prevented), thereby eliminating the needs for a special part or a structure to fix and hold the second housing to the first housing in the closed state and contributing to the cost reduction of the electronic devices.

The light source may be arranged at an upper portion in the wall section and illuminate the operation section in an obliquely downward direction. This enables the light source to well illuminate the operation section that is distant from the wall section.

The operation section may be a keyboard. In addition, the second housing may have a display screen on a face facing the first housing when the second housing is caused to be in a closed state.

As described above, according to the present invention, it is possible to realize an electronic device having high visibility and of low cost.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is an external perspective view of a notebook PC that is a first embodiment of the present invention;

FIG. 2 is a side view of the notebook PC illustrated in FIG. 1;

FIG. 3 is a top view of a calculation unit of the notebook PC illustrated in FIG. 1;

FIG. 4 is a top view of a calculation unit of a notebook PC that is a second embodiment of the present invention;

FIG. 5 is a perspective view of the notebook PC illustrated in FIG. 1, with the display unit closed;

FIG. 6 is an external perspective view of a notebook PC that is a second embodiment of the present invention;

FIG. 7 is an external perspective view of a notebook PC that is a fourth embodiment of the present invention; and

FIG. 8 is an external perspective view of a notebook PC that is a fifth embodiment of the present invention.

### BEST MODE FOR CARRYING OUT THE INVENTION

Hereinafter, embodiments of the present invention will be described with reference to drawings.

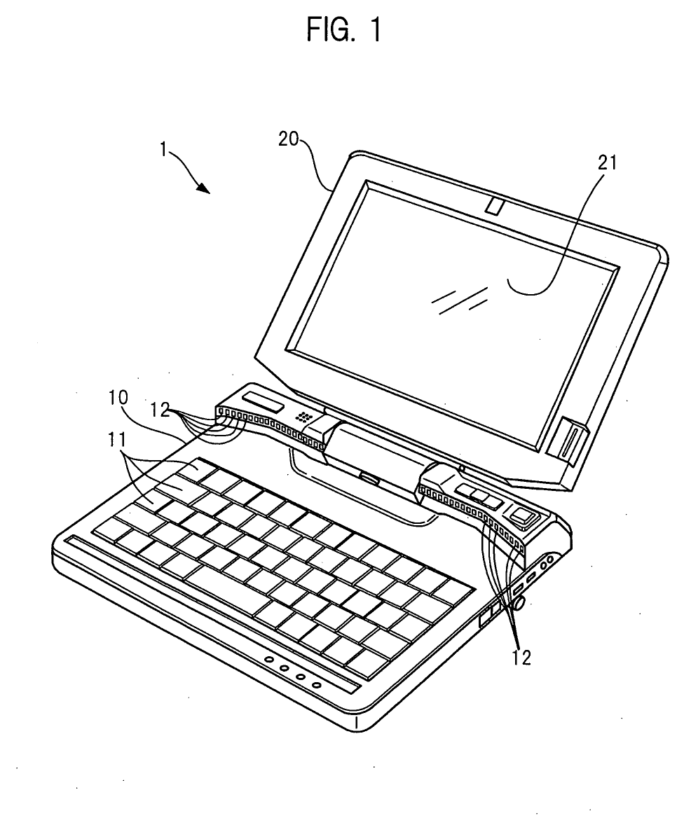

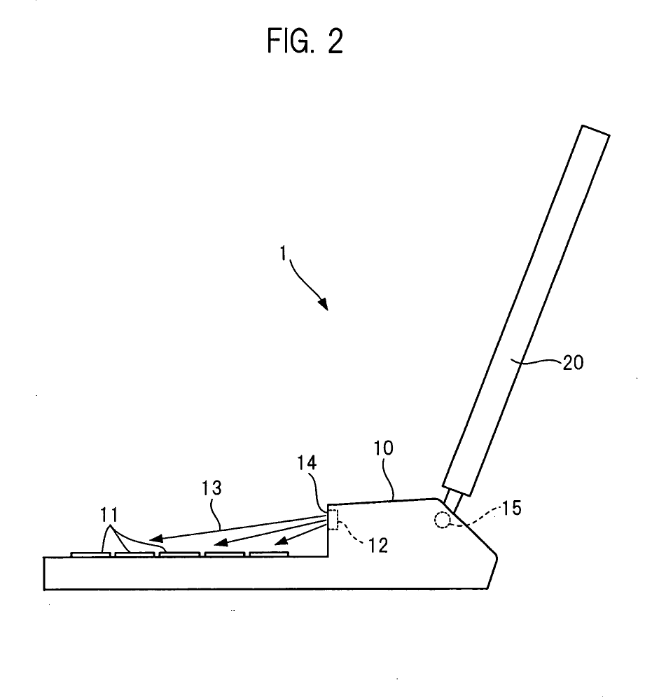

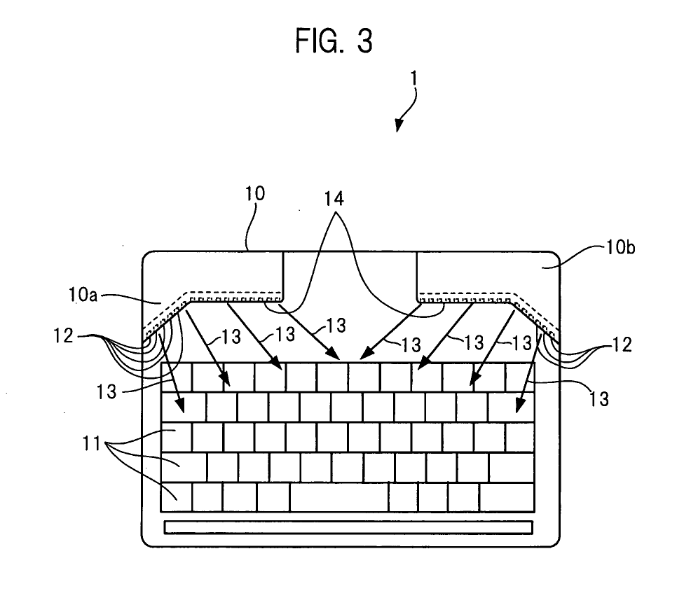

FIG. 1 is an external perspective view of a notebook PC that is a first embodiment of the present invention. FIG. 2 is a side view of the notebook PC illustrated in FIG. 1. FIG. 3 is a top view of a calculation unit of the notebook PC illustrated in FIG. 1.

Incidentally, a notebook PC 1 of the first embodiment corresponds to an example of the first electronic device of the present invention as well as an example of the second electronic device of the present invention.

As illustrated in FIGS. 1 to 3, the notebook PC 1 is an electronic device including a keyboard 11 on its top surface, a calculation unit 10, and a display unit 20. The keyboard 11 is an example of the operation section. The calculation unit 10 is a first housing incorporating an electronic circuit (not illustrated) to perform calculation processing according to an operation of the keyboard 11. The display unit 20 has a display screen 21, and is a second housing connected to the calculation unit 10 with a hinge 15 so as to be openable and closable at a central position in the deep side of the calculation unit 10. The electronic device further includes light sources 12 arranged on both sides in the deep side of the calculation unit 10, to illuminate the keyboard 11 in an obliquely inward direction. LEDs (Light Emitting Diode) having directivity are used as the light sources 12 in each embodiment of the present invention.

The calculation unit 10 has an external shape of an approximately quadrilateral, and its both side sections 10a and 10b positioned in the deep side of the calculation unit 10 (that is, close to one side of the quadrilateral of the calculation unit 10) and on both sides of the hinge 15 have wall sections 14. The wall sections 14 are formed to be higher in one step with standing walls. The light sources 12 are arranged in the wall sections 14 in a posture causing light to be irradiated in an obliquely inward direction. Consequently, as illustrated in FIG. 2, the light sources 12 are positioned at an upper portion of the wall sections 14 to illuminate the keyboard 11 in an obliquely downward direction.

This structure allows light 13 from the light sources 12 to irradiate in an obliquely inward direction to the keyboard 11, and the entire keyboard 11 is illuminated, thereby making the keyboard 11 well visible even in a dark place. Furthermore, since the light 13 from the light sources 12 is irradiated obliquely inwardly to the keyboard 11, the light 13 irradiated from the light sources 12 and light reflected from the keyboard 11 do not enter the eyes of an operator, leaving an operation of the operator unaffected without obstruction. Additionally, since the light from the light sources 12 arranged at the upper portion in the wall sections 14 also reaches the keyboard distant from the light sources 12, high visibility is secured.

Next, a second embodiment of the present invention will be explained.

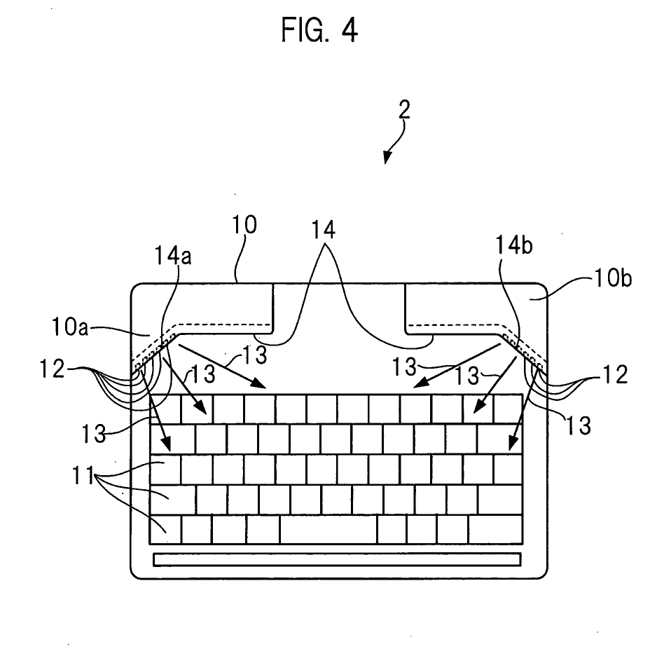

FIG. 4 is a top view of a calculation unit of a notebook PC 2 that is the second embodiment of the present invention.

As illustrated in FIG. 4, in the notebook PC 2 of the second embodiment, sections 10a and 10b of standing walls in wall sections 14 on both sides of a calculation unit are formed obliquely inwardly, and the light sources 12 are arranged in these obliquely inwardly formed sections 14a and 14b of the standing walls. Also in the notebook PC 2, similarly to the notebook PC 1 illustrated in FIG. 1, since the light 13 from the light sources 12 is irradiated in the obliquely inward direction to the keyboard 11 to illuminate the entire keyboard 11, the keyboard may be recognized with high visibility in a dark place. Moreover, since the light 13 from the light sources 12 is irradiated obliquely inwardly to the keyboard 11 and the light 13 irradiated from the light sources 12 and light reflected from the keyboard 11 do not enter the eyes of an operator, leaving an operation of the operator unaffected without obstruction.

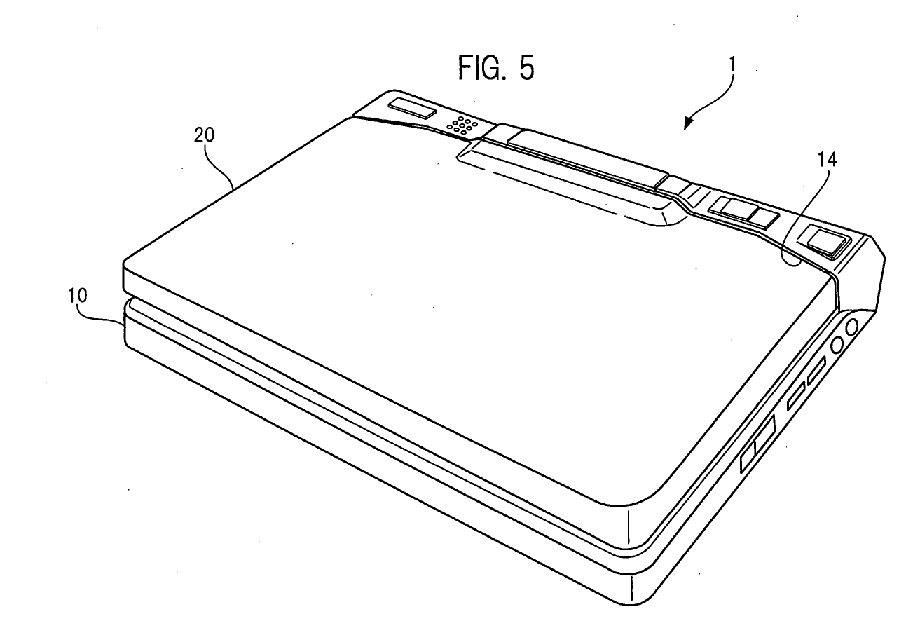

FIG. 5 is a perspective view of the notebook PC 1 illustrated in FIG. 1, with its display unit closed.

As illustrated in FIG. 5, the notebook PC 1 is formed such that, in a state where the display unit 20 is closed, the wall sections 14 of the notebook PC 1 have a height to form a same plane as the display unit 20 closed on the calculation unit 10.

This structure improves safekeeping property and portability of the notebook PC 1, since the display unit 20 and the wall sections 14 forms a same plane when the display unit 20 of the notebook PC 1 is closed.

Next, a third embodiment of the present invention will be explained.

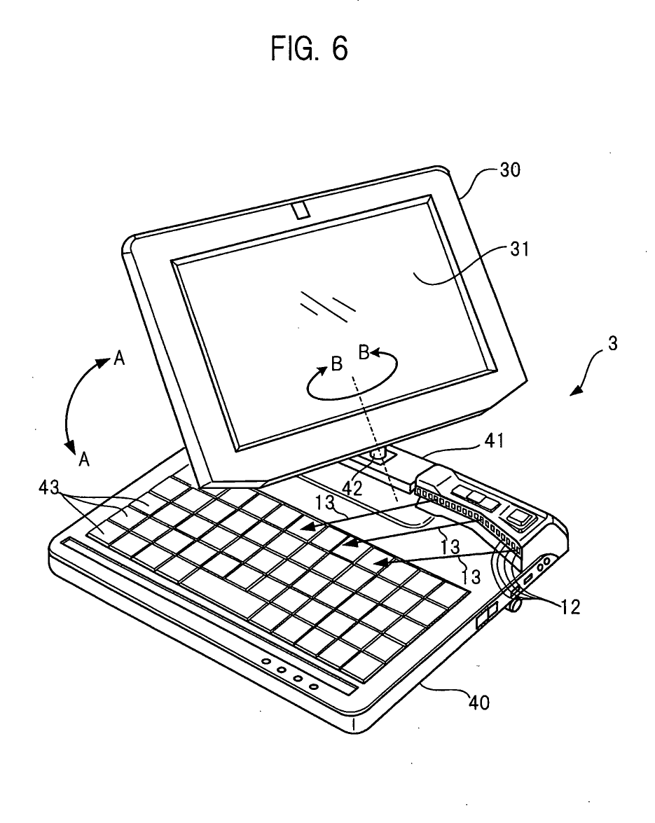

FIG. 6 is an external perspective view of a notebook PC 3 that is the third embodiment of the present invention.

As illustrated in FIG. 6, similarly to the notebook PC 1 illustrated in FIG. 1, the notebook PC 3 is an electronic device including a keyboard 43 on its top surface, a calculation unit 40, and a display unit 30. The calculation unit 40 incorporates an electronic circuit (not illustrated) to perform calculation processing according to an operation of the keyboard 43. The display unit 30 having a display screen 31 is connected openably and closably as well as rotatably to the calculation unit 40 by a two-axis hinge in the deep side of the calculation unit 40. The electronic device further includes light sources 12 arranged in the deep side of the calculation unit 40 on its both sides, to illuminate the keyboard 43 in an obliquely inward direction. Additionally, in the notebook PC 3 of the present embodiment, the display unit 30 is connected openably and closably as well as rotatably to the calculation unit 40 in two axes.

That is, as illustrated in FIG. 6, a display unit supporting section 41 is provided with the notebook PC 3 to hold the display unit 30 openable and closable to the calculation unit 40 in the direction of arrows A-A. Further, a rotating shaft 42 for supporting the display unit 30 rotatably in the direction of arrows B-B to the calculation unit 40 is placed in the display unit supporting section 41. In this way, since the display unit 30 is connected openably and closably as well as rotatably to the calculation unit 40 in two axes, the visibility of the display screen 31 is improved while the display unit 30 is opened to operate the keyboard 43.

Next, a fourth embodiment of the present invention will be explained.

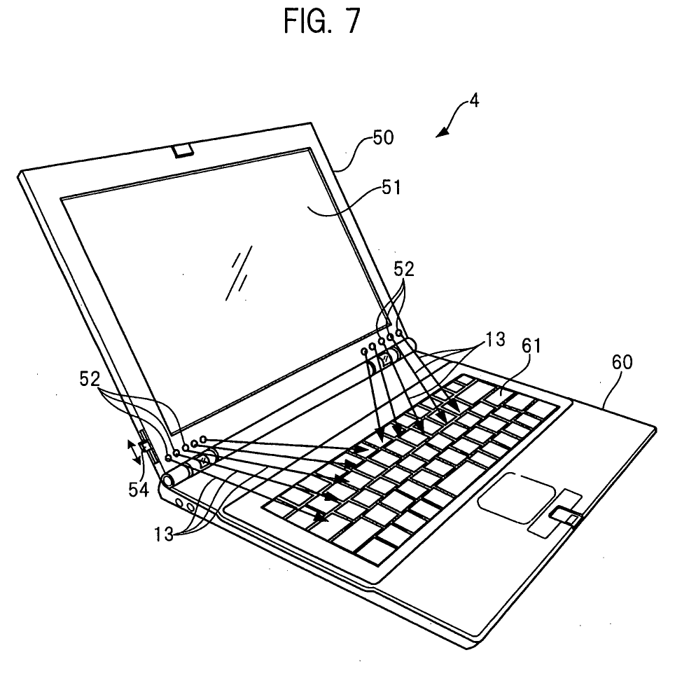

FIG. 7 is an external perspective view of a notebook PC 4 that is the fourth embodiment of the present invention.

The notebook PC 4 in the fourth embodiment corresponds to an embodiment of the second electronic device of the present invention.

As illustrated in FIG. 7, the notebook PC 4 is an electronic device including a keyboard 61 on its top surface, a calculation unit 60, and a display unit 50. The calculation unit 60 incorporates an electronic circuit (not illustrated) to perform calculation processing according to an operation of the keyboard 61. The display unit 50 having a display screen 51 is connected openably and closably to the calculation unit 60 by a hinge in the deep side of the calculation unit 60. The electronic device further includes light sources 52 arranged in the deep side of the notebook PC 4 and on both sides of the display unit 50, to irradiate the keyboard 61 in an obliquely inward direction.

In a lower portion on both sides of the display unit 50, there are arranged adjustment knobs 54 that are slidable up and down for allowing adjustment of an illumination angle of light sources 52 in a vertical direction. An operator may adjust an illumination angle of light 13 from the light sources 52 to the keyboard 61 by sliding the adjustment knobs 54 up and down according to an open angle of the display unit 50.

This structure of the notebook PC 4 allows the light 13 from the light sources 52 to irradiate obliquely inwardly to the keyboard 61, and the entire keyboard 61 is illuminated, making the keyboard 61 well visible even in a dark place. Furthermore, since the light 13 from the light sources 52 is irradiated in the obliquely inward direction to the keyboard 61, and the light 13 irradiated from the light sources 52 and light reflected from the keyboard 61 do not enter the eyes of the operator, and therefore an operation of the operator is unaffected without obstruction.

Next, a fifth embodiment of the present invention will be explained.

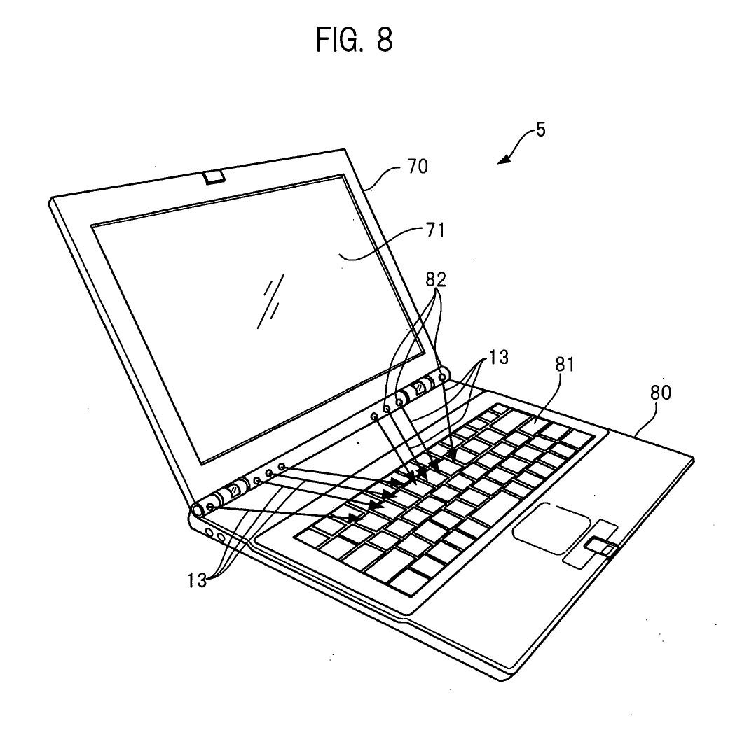

FIG. 8 is an external perspective view of a notebook PC 5 that is the fifth embodiment of the present invention.

The notebook PC 5 in the fifth embodiment corresponds to an embodiment of the second electronic device of the present invention.

As illustrated in FIG. 8, the notebook PC 5 is an electronic device including a keyboard 81 on its top surface, a calculation unit 80, and a display unit 70. The calculation unit 80 incorporates an electronic circuit (not illustrated) to perform calculation processing according to an operation of the keyboard 81. The display unit 70 having a display screen 71 is connected openably and closably to the calculation unit 80 by a hinge in the deep side of the calculation unit 80. The electronic device further includes light sources 82 arranged in the deep side of the calculation unit 80 and on both sides of the calculation unit 80, to illuminate the keyboard 81 obliquely inwardly.

This structure of the notebook PC 5 allows the light 13 from the light sources 82 to irradiate in the obliquely inward direction to the keyboard 81, and the entire keyboard 81 is illuminated, making the keyboard 81 well visible even in a dark place. Furthermore, since the light 13 from the light sources 82 is irradiated obliquely inwardly to the keyboard 81, the light 13 irradiated from the light sources 82 and light reflected from the keyboard 81 do not enter the eyes of the operator, and therefore an operation of the operator is unaffected without obstruction.

Consequently, the notebook PC 5 may have a structure such that the display unit 70 is connected openably and closably as well as rotatably to the calculation unit 80 in two axes. In such a case, by employing a two-axis connection structure similarly to the display unit supporting section 41 and the rotating shaft 42 in the notebook PC 3 illustrated in FIG. 6, it is possible to obtain a structure in which the display unit 70 is openable and closable as well as rotatable with respect to the calculation unit 80.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention has been described in detail, it should be understood that the various changes, substitutions, and alterations could be made hereto without departing from the spirit and scope of the invention.

What is claimed is:

1. An electronic device, comprising:
a calculation unit incorporating a keyboard disposed on a top surface of the electronic device and an electronic circuit to perform calculation processing according to an operation of the keyboard; and
a plurality of light sources arranged in a deep side and on both sides of the calculation unit, to illuminate the keyboard in an obliquely inward direction.

2. The electronic device according to claim 1,
wherein the calculation unit has wall sections formed to be higher in one step with standing walls, in the deep side and at least on both sides of the calculation unit, and
the light sources are arranged in the wall sections.

3. The electronic device according to claim 2,
wherein portions on both sides of the calculation unit of the standing walls are formed in an obliquely inward direction, and
the light sources are arranged in portions formed in the obliquely inward direction of the standing walls.

4. The electronic device according to claim 2, further comprising a display unit having a display screen hinged openably and closably to the calculation unit in the deep side of the calculation unit,
wherein the wall sections are formed to have a height where the wall sections form a same plane as the display unit closed on the calculation unit.

5. The electronic device according to claim 4, wherein the display unit is connected to the calculation unit openably and closably as well as rotatably in two axes.

6. An electronic device comprising:
a calculation unit incorporating a keyboard disposed on a top surface of the electronic device and an electronic circuit to perform calculation processing according to an operation of the keyboard;
a display unit having a display screen hinged openably and closably to the calculation unit in a deep side of the calculation unit; and
a plurality of light sources arranged in the deep side and on both sides of the calculation unit, to illuminate the keyboard in an obliquely inward direction.

7. The electronic device according to claim 6,
wherein the display unit is connected to the calculation unit openably and closably as well as rotatably in two axes.

8. An electronic device, comprising:
a first housing equipped with an operation section on a top surface thereof; and
a second housing being hinged to the first housing openably and closably and having a predetermined thickness,
wherein the first housing comprises:
a wall section including a standing wall having an approximately same height as the predetermined thickness in a portion that does not face the second housing when the second housing is cause to be in a closed state; and
a light source arranged on the wall section to illuminate the operation section.

9. The electronic device according to claim 8,
wherein an external shape of the first housing is approximately quadrilateral,
the second housing is hinged to the first housing at a position lying close to a side of the external shape of the first housing, and
the wall section is formed on a side of the side to which the first housing is hinged.

10. The electronic device according to claim 9,
wherein the second housing is hinged to the first housing at a central position of the side, and
the wall section is formed lying close to both ends from the central position of the side.

11. The electronic device according to claim 8,
wherein the second housing is hinged to the first housing openably and closably as well as rotatably in two axes.

12. The electronic device according to claim 8,
wherein the light source is arranged at an upper portion in the wall section and illuminates the operation section in an obliquely downward direction.

13. The electronic device according to claim 8,
wherein the operation section is a keyboard.

14. The electronic device according to claim 8,
wherein the second housing has a display screen on a face facing the first housing when the second housing is caused to be in a closed state.
